(19) United States
(12) Patent Application Publication
(10) Pub. No.: US 2026/0344048 A1
(43) Pub. Date: Oct. 29, 2026

(54) PIXEL CIRCUIT AND DISPLAY PANEL

(71) Applicant: AUO Corporation, Hsinchu City (TW)

(72) Inventors: Che-Min Lin, Hsinchu City (TW); Kai-Teng Chiang, Hsinchu City (TW); Chun-Ru Huang, Hsinchu City (TW); Chu-Kuan Yu, Hsinchu City (TW); FangMing Tsao, Hsinchu City (TW); Meng-Chiou Huang, Hsinchu City (TW); Yi-Hsin Chou, Hsinchu City (TW); Chun-Hsin Tai, Hsinchu City (TW)

(73) Assignee: AUO Corporation, Hsinchu City (TW)

(21) Appl. No.: 19/390,678

(22) Filed: Nov. 17, 2025

Related U.S. Application Data
(60) Provisional application No. 63/796,419, filed on Apr. 29, 2025.

(30) Foreign Application Priority Data
Sep. 11, 2025 (TW) 114134926

(51) Int. Cl. H10D 86/40; G09G 3/36; H10D 86/60

(52) U.S. Cl. CPC H10D 86/481; G09G 3/3648; H10D 86/441; G09G 2300/0852; G09G 2320/0247; H10D 86/60

(57) ABSTRACT

Provided are a pixel circuit and a display panel. The pixel circuit includes a first transistor, a second transistor, a pixel electrode, a storage capacitor, a coupling capacitor, and an intermediate capacitor. A first source/drain terminal of the first transistor is coupled to a data line. The first transistor is connected in series with a second transistor. Gate terminals of the first transistor and the second transistor are coupled to a gate line. A second source/drain terminal of the second transistor is coupled to the pixel electrode. The storage capacitor is coupled between the pixel electrode and a common electrode. The coupling capacitor is coupled between the gate line and a connection point between the first transistor and the second transistor. The intermediate capacitor is coupled between the connection point and the common electrode.

### CROSS-REFERENCE TO RELATED APPLICATION

This application claims the priority benefit of U.S. provisional application Ser. No. 63/796,419, filed on Apr. 29, 2025, and Taiwan application serial no. 114134926, filed on Sep. 11, 2025. The entirety of each of the above-mentioned patent applications is hereby incorporated by reference herein and made a part of this specification.

### BACKGROUND

### Technical Field

The disclosure relates to a display device, and particularly relates to a pixel circuit and a display panel.

### Related Art

Compared with amorphous silicon (a-Si) thin-film transistor (TFT) technology, low temperature poly-silicon (LTPS) thin-film transistor technology has a higher carrier (electron or hole) mobility and further has a capability to integrate driving circuits on a same glass substrate. Therefore, LTPS technology has undoubtedly become a flat panel display technology with a most potential for a next generation. However, due to a larger leakage current of a LTPS thin-film transistor, a dual-gate thin-film transistor may be utilized in circuit design to reduce the leakage current, so that a downstream thin-film transistor in the dual-gate thin-film transistor has a higher source-drain voltage, affecting a stability of a channel of the dual-gate thin-film transistor.

### SUMMARY

The disclosure provides a pixel circuit and a display panel, which can reduce a source-drain voltage of a downstream transistor in a dual-gate transistor, increase a stability of a channel of the dual-gate transistor, thereby reducing a leakage current of the dual-gate transistor.

The pixel circuit of the disclosure includes a first transistor, a second transistor, a pixel electrode, a storage capacitor, a coupling capacitor, and an intermediate capacitor. The first transistor has a first source/drain terminal coupled to a data line, a gate terminal coupled to a gate line, and a second source/drain terminal. The second transistor has a first source/drain terminal coupled to the second source/drain terminal of the first transistor, a gate terminal coupled to the gate line, and a second source/drain terminal. The pixel electrode is coupled to the second source/drain terminal of the second transistor. The storage capacitor is coupled between the pixel electrode and a common electrode. The coupling capacitor is coupled between the gate line and the second source/drain terminal of the first transistor. The intermediate capacitor is coupled between the second source/drain terminal of the first transistor and the common electrode.

The display panel of the disclosure includes multiple gate lines, multiple data lines, and multiple pixel circuits. Each of the pixel circuits includes a first transistor, a second transistor, a pixel electrode, a storage capacitor, a coupling capacitor, and an intermediate capacitor. The first transistor has a first source/drain terminal coupled to one of the data lines, a gate terminal coupled to one of the gate lines, and a second source/drain terminal. The second transistor has a first source/drain terminal coupled to the second source/drain terminal of the first transistor, a gate terminal coupled to one of the gate lines, and a second source/drain terminal. The pixel electrode is coupled to the second source/drain terminal of the second transistor. The storage capacitor is coupled between the pixel electrode and a common electrode. The coupling capacitor is coupled between the gate line and the second source/drain terminal of the first transistor. The intermediate capacitor is coupled between the second source/drain terminal of the first transistor and the common electrode.

Based on the above, according to the pixel circuit and the display panel of the embodiments of the disclosure, the intermediate capacitor has a voltage buffer function for the second transistor, can stabilize the source-drain voltage of the transistor, thereby lessening a rise of the source-drain voltage of the second transistor when being turned off, increasing the stability of the channel of the dual-gate transistor, and further reducing the leakage current of the dual-gate transistor.

In order to make the features and advantages of the disclosure more comprehensible, the following examples are given and described in detail with the accompanying drawings as follows.

### BRIEF DESCRIPTION OF THE DRAWINGS

FIG. 1 is a circuit schematic view of a pixel circuit according to an embodiment of the disclosure.

FIG. 2 is a schematic cross-sectional view of a portion of the pixel circuit of FIG. 1 according to an embodiment of the disclosure.

FIG. 3 is a system schematic view of a display panel according to an embodiment of the disclosure.

### DESCRIPTION OF THE EMBODIMENTS

Unless otherwise defined, the terms used throughout the specification (including both technical and scientific terms) have the same meanings as understood by those skilled in the art. It should be further understood that, terms such as those defined in commonly used dictionaries should be interpreted as having meanings consistent with the meanings in the related art and the context of the invention, and shall not be interpreted as having idealized or overly formal meanings, unless definitely defined in the content.

It should be understood that, although the terms “first”, “second”, “third”, or the like may be used herein to describe various elements, components, regions, layers, and/or portions, these elements, components, regions, and/or portions should not be limited by these terms. These terms are only used to distinguish one element, component, region, layer, or portion from another element, component, region, layer, or portion. Thus, “first element,” “component,” “region,” “layer,” or “portion” discussed below could be termed a second element, component, region, layer, or portion without departing from the teachings herein.

The terminology used herein is for the purpose of describing particular embodiments and is not intended to be limiting of the invention. As used herein, the singular forms “a,” “an” and “the” are intended to include the plural forms as well, unless the context clearly indicates otherwise. “or” represents “and/or”. The term “and/or” used herein includes any or a combination of one or more of the associated listed items. It will be further understood that the terms “comprises,” “comprising,” “includes” and/or “including,” when used herein, specify the presence of stated features, regions, integers, steps, operations, elements, and/or components, but do not preclude the presence or addition of one or more other features, regions, integers, steps, operations, elements, components, and/or groups thereof.

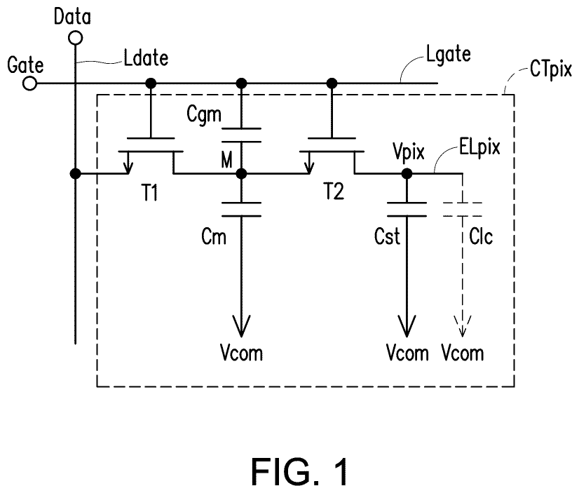

FIG. 1 is a circuit schematic view of a pixel circuit according to an embodiment of the disclosure. Please refer to FIG. 1. In the embodiment, a pixel circuit CTpix includes transistors T1 to T2 (corresponding to a first transistor and a second transistor), a coupling capacitor Cgm, an intermediate capacitor Cm, a pixel electrode ELpix, and a storage capacitor Cst. The transistors T1 to T2 take a P-type transistor as an example. However, the embodiment of the disclosure is not limited thereto.

The transistor T1 has a first source/drain terminal coupled to a data line Ldate, a gate terminal coupled to a gate line Lgate, and a second source/drain terminal. The data line Ldate is configured to receive a pixel data Data. The gate line Lgate is configured to receive a gate signal Gate. The transistor T2 has a first source/drain terminal coupled to the second source/drain terminal of the transistor T1, a gate terminal coupled to the gate line Lgate, and a second source/drain terminal. The transistors T1 to T2 are coupled as a dual-gate transistor. There is a coupling node M between the transistors T1 to T2.

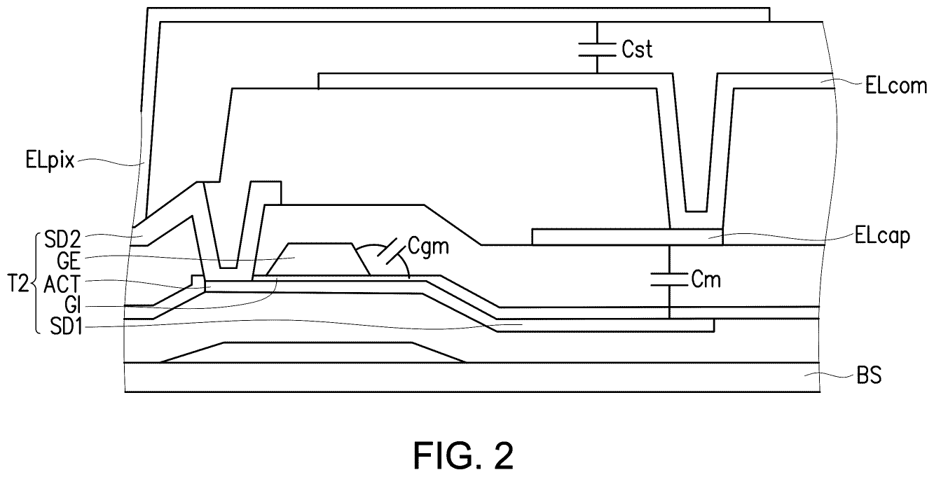

The coupling capacitor Cgm is coupled between the gate line Lgate and the second source/drain terminal of the transistor T1, that is, coupled between the gate line Lgate and the coupling node M. The intermediate capacitor Cm is coupled between the second source/drain terminal of the transistor T1 and a common electrode (a common electrode ELcom as shown in FIG. 2), that is, coupled between the coupling node M and the common electrode (or a common voltage Vcom). The common electrode is configured to receive the common voltage Vcom. The pixel electrode ELpix is coupled to the second source/drain terminal of the transistor T2. The storage capacitor Cst is coupled between the pixel electrode ELpix and the common electrode ELcom. The storage capacitor Cst is formed in a region where a dielectric layer (or a dielectric material) is configured between the pixel electrode ELpix and the common electrode ELcom.

When a liquid crystal layer is configured between the pixel electrode ELpix and the common electrode ELcom, a liquid crystal capacitor Clc is formed between the pixel electrode ELpix and the common electrode ELcom.

Based on the above, when the gate signal Gate turns off the transistors T1 and T2, if a voltage level of the pixel data Data is higher than a pixel voltage Vpix, the intermediate capacitor Cm may absorb a leakage current from the transistor T1, lessening a rise of a source-drain voltage of the transistor T2. On the other hand, when the gate signal Gate turns on the transistors T1 and T2, the pixel data Data, a voltage of the coupling node M, and the pixel voltage Vpix have a same voltage due to charging. At this time, an increase of the intermediate capacitor Cm may functionally stabilize the voltage of the coupling node M (that is, the voltage of the coupling node M is not easily changed). Therefore, when the gate signal Gate turns off the transistors T1 and T2, and there is a voltage difference between the pixel data Data and the pixel voltage Vpix, and a leakage current is generated, since the voltage of the coupling node M is not easily changed, a voltage difference between the voltage of the coupling node M and the pixel voltage Vpix may not be so large, which may reduce a voltage difference between a source and a drain of the transistor T2, so that the transistor T2 leaks less. Therefore, regardless of the voltage level of the pixel data Data and the pixel voltage Vpix, the intermediate capacitor Cm has a voltage buffer function for the transistor T2 to stabilize the source-drain voltage of the transistor T2, thereby improving a stability of a channel of the dual-gate transistor formed by the transistors T1 to T2, and further reducing the leakage current of the dual-gate transistor.

In the embodiment of the disclosure, if a capacitance value of the intermediate capacitor Cm is greater, a loss amplitude of the voltage of the coupling node M within a same period is less, thus reducing the source-drain voltage of the transistor T2, leading to a lower leakage of the transistor T2.

In the embodiment of the disclosure, the coupling capacitor Cgm may be an equivalent capacitance between the gate and the first source/drain terminal of the second transistor T2. However, the embodiment of the disclosure is not limited thereto.

In the embodiment of the disclosure, the transistors T1 and T2 may individually be a low temperature poly-silicon (LTPS) transistor. However, the embodiment of the disclosure is not limited thereto.

TABLE 1

| | | | | | | | |
|---|---|---|---|---|---|---|---|
| C_{M} (pF) | 0 | 0.001 | 0.005 | 0.011 | 0.023 | 0.03 | 0.05 |
| ΔV(%) | 100% | 74.6% | 35.7% | 20.1% | 10.8% | 8.6% | 5.5% |
| LRR | −40 dB | | | −55 dB | −60 dB | | |

In the embodiment of the disclosure as shown in Table 1, a capacitance value of the storage capacitor Cst is, for example, 1.9 picofarads (pF). A capacitance value of the coupling capacitor Cgm is, for example, 0.00093 pF. As shown in Table 1, when a capacitance value C_{M} of the intermediate capacitor Cm is higher, a voltage variation ΔV of the pixel voltage Vpix of the pixel electrode ELpix decreases. Moreover, in an operating condition of a low refresh rate (LRR) (such as 1 hertz (Hz)), in response to an increase of the capacitance value C_{M} of the intermediate capacitor Cm, a flicker performance related to a leakage current of the pixel circuit CTpix may be improved, for example, increasing from −40 dB to −55 dB or −60 dB.

When the gate signal Gate turning off the transistors T1 and T2 (that is, the transistors T1 and T2 are cut) is considered, a coupling induced by the coupling capacitor Cgm increases the source-drain voltage of the transistor T2, resulting in a greater leakage current. Therefore, it might be needed to adjust a magnitude of the capacitance value C_{M} of the intermediate capacitor Cm according to a capacitance value of the coupling capacitor Cgm. That is, a capacitance value of the intermediate capacitor Cm may be related to a capacitance value of the coupling capacitor Cgm.

TABLE 2

| | | | | | | |
|---|---|---|---|---|---|---|
| C_{GM} (pF) | 0.00096 | 0.00192 | 0.00288 | 0.0048 | 0.00768 | 0.01056 |
| C_{GM} | 3.95% | 4.15% | 4.16% | 4.17% | 4.20% | 4.13% |
| ratio (%) | | | | | | |
| C_{M} (pF) | 0.023 | 0.044 | 0.066 | 0.11 | 0.175 | 0.245 |

In the embodiment of the disclosure as shown in Table 2, a magnitude of the capacitance value C_{M} of the intermediate capacitor Cm is adjusted according to a capacitance value of the coupling capacitor Cgm. A capacitance value of the storage capacitor Cst is, for example, 1.9 pF. At this time, a voltage of the coupling node M is determined by the capacitance value C_{GM} of the coupling capacitor Cgm and the capacitance value C_{M} of the intermediate capacitor Cm. The voltage of the coupling node M also affects a leakage current of the transistor T2. Therefore, retaining a ratio of the capacitance value C_{GM} of the coupling capacitor Cgm and the capacitance value C_{M} of the intermediate capacitor Cm may implement a same flicker performance. For example, in a condition where a flicker performance at a low refresh rate is −60 dB, the capacitance value C_{M} of the intermediate capacitor Cm≥23.072*C_{GM}−0.0002.

On the other hand, in the embodiment of the disclosure, a size of different storage capacitors Cst may affect a ratio of the capacitance value C_{GM} of the coupling capacitor Cgm and the capacitance value C_{M} of the intermediate capacitor Cm, as well as the capacitance value C_{M} of the intermediate capacitor Cm. Therefore, when a capacitance value C_{ST} of the storage capacitor Cst and the capacitance value C_{GM} of the coupling capacitor Cgm are known, a recommended value of the capacitance value C_{M} of the intermediate capacitor Cm may be estimated according to a formula. That is, the capacitance value C_{M} of the intermediate capacitor Cm may be related to a capacitance value of the coupling capacitor Cgm and a capacitance value C_{ST} of the storage capacitor Cst.

TABLE 3

| | | | | | | |
|---|---|---|---|---|---|---|
| C_{ST} (pF) | 0.475 | 0.627 | 0.95 | 1.9 | 2.85 | 3.8 |
| | (0.25x) | (0.33x) | (0.5x) | (1x) | (1.5x) | (2x) |
| C_{GM} | 0.90% | 1.18% | 1.87% | 3.95% | 6.26% | 8.47% |
| ratio (%) | | | | | | |
| C_{M} (pF) | 0.105 | 0.008 | 0.005 | 0.023 | 0.014 | 0.01 |

Furthermore, in a condition where a flicker performance at a low refresh rate is −60 dB, C_{GM} ratio=C_{GM}/(C_{M}+C_{GM})=0.0229*C_{ST}−0.0027. After simplification, the capacitance value C_{M} of the intermediate capacitor Cm≥C_{GM}/(0.0229*C_{ST}-0.0027)−C_{GM} may be obtained. A value may refer to Table 3. The capacitance value C_{GM} of the coupling capacitor Cgm is, for example, 0.00096 pF.

FIG. 2 is a schematic cross-sectional view of a portion of the pixel circuit of FIG. 1 according to an embodiment of the disclosure. Please refer to FIG. 1 and FIG. 2. In the embodiment, the transistors T1 and T2 are individually a low temperature poly-silicon (LTPS) transistor. A structure of the transistor T2 is shown here for illustration. In the embodiment, based on a position of a substrate BS, the transistor T2 is a top-gate transistor. A gate electrode GE is disposed on a semiconductor layer forming an active region ACT and a first source/drain terminal SD1 with a gate insulating layer GI interposed therebetween. That is, in each of the transistors T1 and T2, the first source/drain terminal SD1 shares a same semiconductor layer with the active region ACT. The semiconductor layer may be differentiated (or formed) into the active region ACT and the first source/drain terminal SD1 through different doping levels.

In the embodiment, a coupling of the gate electrode GE and the first source/drain terminal SD1 forms the coupling capacitor Cgm. A second source/drain terminal SD2 is in contact with the active region ACT through a through hole in the gate insulating layer GI. A capacitor electrode ELcap in contact with the common electrode ELcom may be formed over the first source/drain terminal SD1. The intermediate capacitor Cm is composed of (or formed by) the first source/drain terminal SD1 of the semiconductor layer and the capacitor electrode ELcap. Therefore, through adjusting an overlapping region of the first source/drain terminal SD1 and the capacitor electrode ELcap, a capacitance value of the intermediate capacitor Cm may be adjusted. Moreover, the pixel electrode ELpix is in contact with the second source/drain terminal SD2, and forms (or composes) the storage capacitor Cst with the common electrode ELcom.

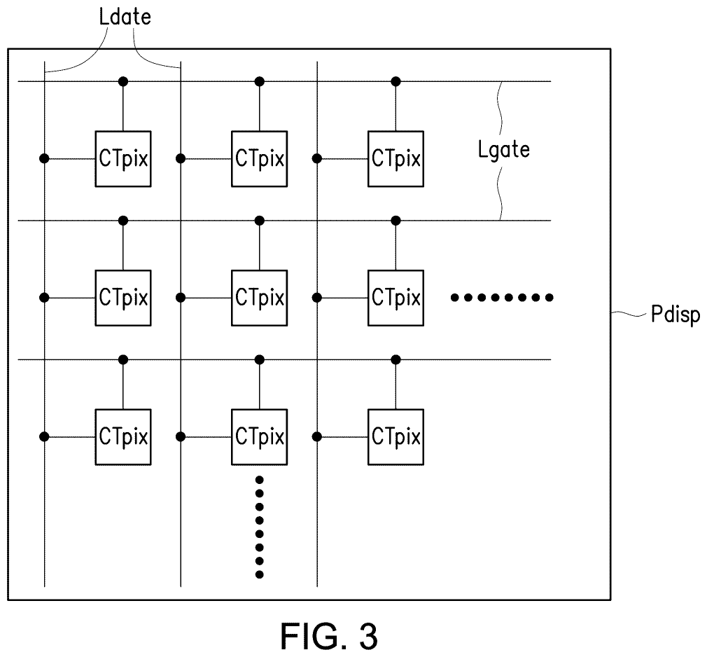

FIG. 3 is a system schematic view of a display panel according to an embodiment of the disclosure. Please refer to FIG. 1 and FIG. 3. In the embodiment, a display panel Pdisp includes the multiple gate lines Lgate, the multiple data lines Ldate, and the multiple pixel circuits CTpix. The gate lines Lgate extend, for example, horizontally. The data lines Ldate, for example, extend vertically (that is, for example, being perpendicular to the gate lines Lgate). The pixel circuits CTpix are, for example, arranged in an array. Each of the pixel circuits CTpix is coupled to one of the data lines Ldate and one of the gate lines Lgate. The pixel circuits CTpix may refer to the embodiment shown in FIG. 1. However, the embodiment of the disclosure is not limited thereto.

In summary, according to the pixel circuit and the display panel of the embodiments of the disclosure, the intermediate capacitor has the voltage buffer function for a downstream transistor, can stabilize the source-drain voltage of the transistor, thereby lessening a rise of the source-drain voltage of the downstream transistor when being turned off, improving the stability of the channel of the dual-gate transistor, and further reducing the leakage current of the dual-gate transistor.

Although the disclosure has been disclosed in the above embodiments, the embodiments are not intended to limit the disclosure. Persons skilled in the art may make some changes and modifications without departing from the spirit and scope of the disclosure. Therefore, the protection scope of the disclosure shall be defined by the appended claims.

To the claims:

1. A pixel circuit, comprising:
a first transistor, having a first source/drain terminal coupled to a data line, a gate terminal coupled to a gate line, and a second source/drain terminal;
a second transistor, having a first source/drain terminal coupled to the second source/drain terminal of the first transistor, a gate terminal coupled to the gate line, and a second source/drain terminal;
a pixel electrode, coupled to the second source/drain terminal of the second transistor;
a storage capacitor, coupled between the pixel electrode and a common electrode;
a coupling capacitor, coupled between the gate line and the second source/drain terminal of the first transistor, wherein a terminal of the coupling capacitor is coupled to the gate terminals of the first transistor and the second transistor by coupling to the gate line; and
an intermediate capacitor, coupled between the second source/drain terminal of the first transistor and the common electrode.

2. The pixel circuit according to claim 1, wherein a capacitance value of the intermediate capacitor is related to a capacitance value of the coupling capacitor.

3. The pixel circuit according to claim 2, wherein the capacitance value of the intermediate capacitor is greater than or equal to 23.072*C_{GM}−0.0002, wherein C_{GM} is the capacitance value of the coupling capacitor.

4. The pixel circuit according to claim 2, wherein the capacitance value of the intermediate capacitor is related to the capacitance value of the coupling capacitor and a capacitance value of the storage capacitor.

5. The pixel circuit according to claim 4, wherein the capacitance value of the intermediate capacitor is greater than or equal to (C_{GM}/(0.0229*CST−0.0027)−C_{GM}), wherein C_{GM} is the capacitance value of the coupling capacitor, and CST is the capacitance value of the storage capacitor.

6. The pixel circuit according to claim 1, wherein the first transistor and the second transistor are individually a low temperature poly-silicon (LTPS) transistor.

7. The pixel circuit according to claim 6, wherein the first source/drain terminal of each of the first transistor and the second transistor shares a same semiconductor layer with an active region of each of the first transistor and the second transistor.

8. The pixel circuit according to claim 7, wherein the intermediate capacitor is composed of the semiconductor layer and a capacitor electrode in contact with the common electrode.

9. A display panel, comprising:
a plurality of gate lines;
a plurality of data lines; and
a plurality of pixel circuits, wherein each of the pixel circuits comprises:
a first transistor, having a first source/drain terminal coupled to one of the data lines, a gate terminal coupled to one of the gate lines, and a second source/drain terminal;
a second transistor, having a first source/drain terminal coupled to the second source/drain terminal of the first transistor, a gate terminal coupled to the one of the gate lines, and a second source/drain terminal;
a pixel electrode, coupled to the second source/drain terminal of the second transistor;
a storage capacitor, coupled between the pixel electrode and a common electrode;
a coupling capacitor, coupled between the gate line and the second source/drain terminal of the first transistor, wherein a terminal of the coupling capacitor is coupled to the gate terminals of the first transistor and the second transistor by coupling to the gate line; and
an intermediate capacitor, coupled between the second source/drain terminal of the first transistor and the common electrode.

10. The display panel according to claim 9, wherein a capacitance value of the intermediate capacitor is related to a capacitance value of the coupling capacitor.

11. The display panel according to claim 10, wherein the capacitance value of the intermediate capacitor is greater than or equal to 23.072*C_{GM}−0.0002, wherein C_{GM} is the capacitance value of the coupling capacitor.

12. The display panel according to claim 10, wherein the capacitance value of the intermediate capacitor is related to the capacitance value of the coupling capacitor and a capacitance value of the storage capacitor.

13. The display panel according to claim 12, wherein the capacitance value of the intermediate capacitor is greater than or equal to (C_{GM}/(0.0229*CST−0.0027)−C_{GM}), wherein C_{GM} is the capacitance value of the coupling capacitor, and CST is the capacitance value of the storage capacitor.

14. The display panel according to claim 9, wherein the first transistor and the second transistor are individually a low temperature poly-silicon (LTPS) transistor.

15. The display panel according to claim 14, wherein the first source/drain terminal of each of the first transistor and the second transistor shares a same semiconductor layer with an active region of each of the first transistor and the second transistor.

16. The display panel according to claim 15, wherein the intermediate capacitor is composed of the semiconductor layer and a capacitor electrode in contact with the common electrode.
